(19) United States
(12) Patent Application Publication
(10) Pub. No.: US 2004/0186810 A1
(43) Pub. Date: Sep. 23, 2004

(54) Method of supplying sputtering targets to fabricators and other users

(76) Inventors: Christopher A. Michaluk, Gilbertsville, PA (US); Matthew T. Stershic, Downingtown, PA (US); Robert B. Ford, Washington Court House, OH (US)

Correspondence Address: Martha Ann Finnegan, Esq., Cabot Corporation, 157 Concord Road, Billerica, MA, 01821-7001, US

(21) Appl. No.: 10/367,615

(22) Filed: Feb. 14, 2003

(51) Int. Cl. C23C 14/32; G06F 17/60; G06F 17/00; G06G 7/00

(52) U.S. Cl. 705/400; 705/1

(57) ABSTRACT

A method of supplying a sputter target, including, supplying a sputtering target assembly to a user or an agent thereof where a sputter target of the sputtering target assembly is sputtered to form a spent target assembly; determining an amount of the sputter target consumed by the sputtering; and charging the user based on the amount sputtered or an amount not returned, is described.

### BACKGROUND OF THE INVENTION

The present invention relates to a method of supplying a sputter target to a user for forming sputtered articles, and more particularly, to a method of supplying the sputter target to a user in which the supplier charges for only the amount of the sputter target which is consumed in the sputtering process.

In industry, fabrication of sputtered articles typically generates a sputtering target assembly that is eroded or spent. To the extent that it is unusable for further sputtering, such spent target assembly is an undesirable byproduct of the sputtering process, such that the value lost in downgrading unused target material from its purchase price to its scrap price can represent a significant portion of the total fabricating cost that is reflected in the price of sputtered articles. Under the traditional business model, costs associated with spent target assembly generation are bore almost entirely by the fabricator.

In the sputter application field, the typical supply chain of sputter material includes a primary metal processor who processes metal ores and raw materials into metals or alloys thereof (or fine metal-containing material such as oxide, nitride, silicide, etc.), typically of a high purity. Refinement of the metal material by such processing produces melt feedstock. As its name suggests, the melt feedstock is then melted or otherwise consolidated by the primary metal processor into forms such as ingots that are then further processed into shapes or mill forms such as billets, rods, plates, or discs. The mill forms are then sold to a sputtering target manufacturer. The target manufacturer then performs additional refinement techniques on the mill forms prior to fabricating the material to produce a finished sputtering target assembly comprising a precision-machined metal target or metal target blank attached to a backing plate.

Hence, the sputtering target manufacturer creates value by performing steps of metalworking on the mill forms purchased from the primary metal processor to form a metal target, bonding the metal target onto a backing plate, and machining, polishing, or otherwise surface conditioning the finished sputtering target assembly. The sputtering target assembly is then sold to a sputterer or fabricator of sputtered articles. The fabricator then uses the sputter target in a sputtering process to fabricate sputtered articles such as thin film layers on electronic components. Because the sputtering process does not erode or sputter the target evenly, sputtering invariably results in the formation of an unusable incompletely eroded sputter target, or, a spent target assembly.

Because salvaged spent target assemblies can be sold back into the sputtering target manufacture chain, the value of a spent target generated during the sputtering process performed by the fabricator is equivalent to the value of the melt feedstock. Therefore, the “downgrade” costs of spent target generation is equivalent to the total value created somewhere between the melt feedstock stage and the finished sputtering target assembly, plus the profit associated with the intervening sale of the target material. The scrap downgrade costs can represent a significant portion of the fabricator's total manufacturing costs, and are accordingly passed along to its customers in the form of higher prices for the finished product.

Accordingly, a need exists for a method of supplying a sputter target whereby the value lost by the generation of spent sputtering assemblies in sputtering processes performed by a fabricator of sputtered articles can be significantly reduced.

### SUMMARY OF THE PRESENT INVENTION

It is therefore a feature of the present invention to provide a method of supplying a sputter target to a fabricator or other user for sputtering such that the value lost by the generation of spent target assemblies in sputtering processes performed by the user are significantly reduced.

It is another feature of the present invention to provide a sputtering target to a user that consumes a portion of the finished sputter target, such that the value lost by the user in reclaiming the remaining spent target is significantly reduced.

Additional features and advantages of the present invention will be set forth in part in the description that follows, and in part will be apparent from the description, or may be learned by practice of the present invention. The objectives and other advantages of the present invention will be realized and attained by means of the elements and combinations particularly pointed out in the description and appended claims.

To achieve these and other advantages, and in accordance with the purposes of the present invention, as embodied and broadly described herein, the present invention is directed to a method of supplying a sputter target to a fabricator or other user for use in sputtering processes in which a spent target assembly is formed, determining an amount of the sputter target consumed by sputtering, and charging the user for that amount or for an amount not returned by the user. The method optionally further includes returning by the user or the user's agent the spent target assembly to the supplier or the supplier's agent.

In one embodiment of the present invention, the method includes charging the user a fee for the spent target assembly that is returned by the user.

In another embodiment of the present invention, the sputter target comprises a valve metal, including tantalum, niobium, and alloys thereof.

In another embodiment of the present invention, the sputter target comprises high purity titanium, aluminum, or copper.

In another embodiment of the present invention, supplying the sputter target to the user comprises a bailment.

In another embodiment of the present invention, the step of charging the user occurs at predetermined intervals.

In yet another embodiment of the present invention, the step of charging the user occurs upon return of the spent target assembly to the supplier.

In another embodiment of the present invention, the user is charged an interest fee on the value of the sputter target during the time period it is retained by the user.

Another embodiment involves charging a fee to the user that occurs upon delivery of the sputter target assembly.

It is to be understood that both the foregoing general description and the following detailed description are exemplary and explanatory only and are intended to provide a further explanation of the present invention, as claimed.

### BRIEF DESCRIPTION OF THE DRAWINGS

FIGS. 1 and 2 are block diagrams. FIG. 1 shows the various steps in a conventional sputter target transaction and FIG. 2 shows an embodiment of the present invention.

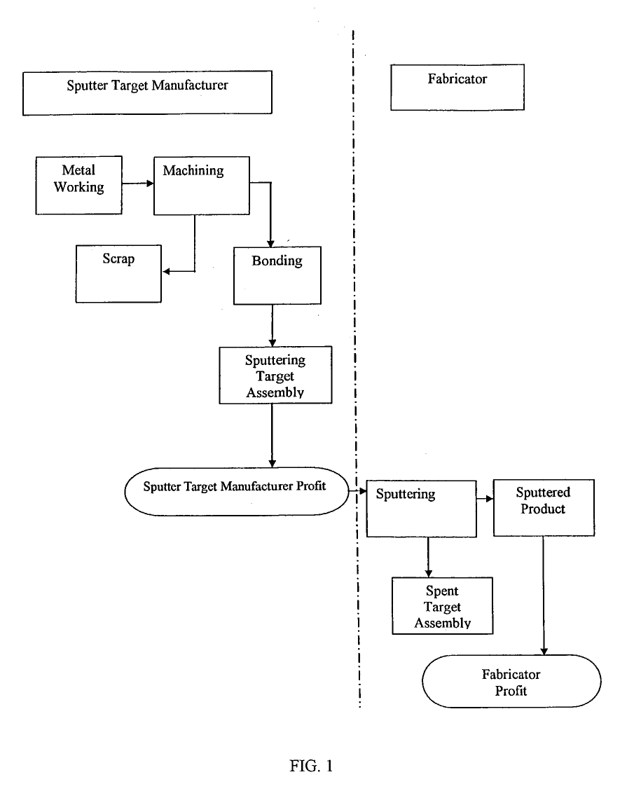

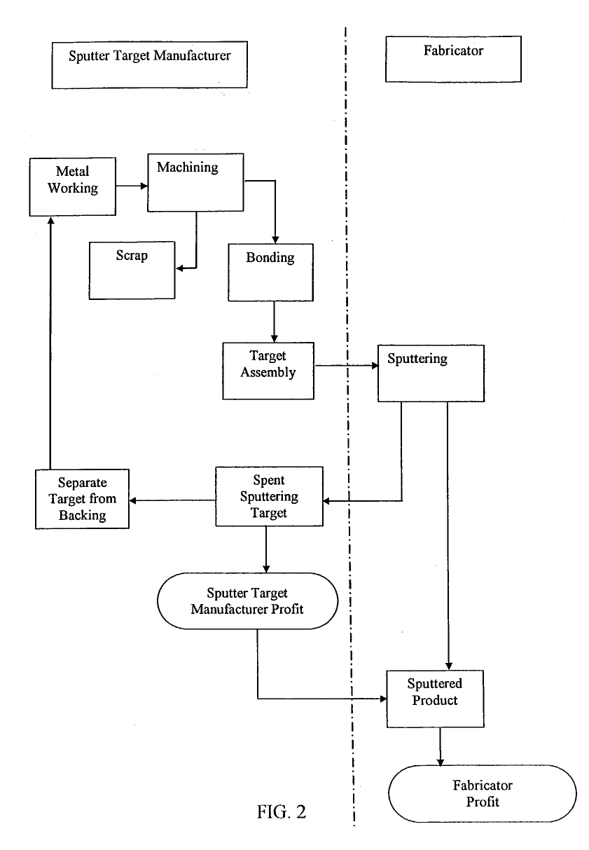

### DETAILED DESCRIPTION OF THE PRESENT INVENTION

The present invention is directed to a method of supplying a sputter target to a fabricator or other user. The method includes supplying a sputtering target assembly to a user or an agent of the user where a sputter target of the sputtering target assembly is sputtered to form a spent target assembly; determining an amount of the sputter target consumed by the sputtering; and charging the user for the amount consumed or an amount of sputter target not returned by the user. The spent target assembly can optionally be returned by the user or an agent of the user to the supplier or an agent of the supplier.

In more detail, the sputter target supplied can have any dimensions and preferably conforms to the dimensional requirements specified by the original equipment manufacturer (OEM). The sputter target can be a planar cathode, for example, in the shape of a disc or a rectangle. Alternatively, the cathode can be near net-shaped as in a hollow cathode magnetron (HCM) sputter target, with or without cladding, as described for example, in U.S. patent application Ser. No. 10/036,338 filed Nov. 9, 2001, and in U.S. Pat. No. 6,283,357 B1 (Kulkarni et al.), both of which are incorporated in their entirety herein by reference.

The sputter target can be made of any material that can be sputtered or eroded in a sputtering or deposition process. Examples of sputter target material include, but are not limited to, tantalum, niobium, cobalt, titanium, copper, aluminum, and alloys thereof. The target can be made from target grade material, for instance, as described in U.S. Pat. No. 6,348,113 (Michaluk et al.), incorporated in its entirety herein by reference. The purity, texture, and/or grain size and other properties, including size and the like are not critical to the present invention. The powder used to make the target as well as the target itself can have any purity with respect to the metal. For instance, the purity can be 99% or greater, such as from about 99.5% or greater, and more preferably 99.95% or greater, and even more preferably 99.99% or greater or 99.995% or greater or 99.999% or greater. The target can have any suitable grain size (e.g., average grain sizes of less than 300 microns, less than 100 microns, less than 50 microns, less than 20 microns) and/or texture. For instance, the texture can be random, a primary (111) texture, or a primary (100) texture that can be on the surface or throughout the entire volume of the target. Preferably, the texture is uniform. Also, the target can have a mixed (111):(110) texture throughout the surface or throughout the entire volume of the target. In addition, the target can be substantially void of textural banding, such as substantially void of (100) textural banding.

The backing plate can be any suitable metal material usable as a backing plate in sputtering applications. Examples of the backing plate material include, but are not limited to, copper, or a copper alloy, tantalum, niobium, cobalt, titanium, aluminum, and alloys thereof, such as TaW, NbW, TaZr, NbZr, TaNb, NbTa, TaTi, NbTi, TaMo, NbMo, TaAl, TaSi, and the like. The backing plate can be coated with a concealing layer or interlayer.

No limitation exists as to the type of material from which the target and the backing plate can be made. The thickness of the backing plate and the target can be any suitable thickness used in sputtering target assemblies. Examples of suitable thicknesses of the backing plate and of the target include, but are not limited to, a backing plate with a thickness of from about 0.25 or less to about 2 inches or more, and a target with a thickness ranging from about 0.06 inches to about 1 inch or more.

The sputtering target assembly can be of any type, and the design, the materials from which it is made, the specific components, the intended use, the method of manufacture, and the like, are not critical to the present invention. The sputtering target assembly can be one that has a target and a backing plate attached directly or indirectly to one another by any suitable technique, the technique preferably being bonding. The bond can be a metallurgical bond, such as a bond achieved by diffusion bonding, explosion bonding, electron beam welding, inertia welding, friction brazing, and the like, or by soldering techniques. The target and the backing plate can also be attached by any mechanical method or device. One or more interlayers or bonding layers can be located between the target and the backing plate and attached or bonded to one or both. The interlayer can be made of any suitable metal, including the metals discussed above for targets and backing plates. The target and the backing plate can be made of the same or of dissimilar metals. The sputtering target assembly used to practice the present invention can be a monolithic sputtering target as described, for example, in U.S. patent application Ser. No. 60/397,418 filed on Jul. 19, 2002, which is incorporated in its entirety herein by reference.

As to supplying a sputtering target assembly to a user where the target is sputtered to form a spent target assembly, the sputtering target assembly can be supplied by any supplier, for example, a metal fabricator or agent thereof. Preferably, the supplier is a sputtering target manufacturer or sub-contractor thereof. The user can be any sputterer or fabricator who sputters the target of the sputtering target assembly to form a sputtered product such as a thin film layer, which also results in the formation of an eroded or spent target assembly. The sputtering target assembly can be supplied for a predetermined amount of time, effectively “checked-out.”

As to determining an amount of the sputter target consumed by sputtering, any suitable method for quantitatively measuring the amount of eroded or sputtered target material can be used in practicing the present application. For example, the mass of the sputtering target assembly can be measured anytime prior to being sputtered by the user. Subsequently, the mass of the spent target assembly can be measured any time thereafter. A comparison between the measured masses of the sputtering target assembly and the spent target assembly can then be used to determine the amount of target material consumed by the user in sputtering. Alternatively, the mass of the sputter target independent of the backing plate can be measured anytime prior to being sputtered by the user, for example, before the target is bonded to the backing plate. Subsequently, the mass of the sputtered target can be measured, for example, after separating the sputtered target from the spent target assembly. A comparison between the measured masses of the supplied sputter target and the sputtered target can be used to determine the amount of target material consumed by the user. Methods used to measure the masses according to the present invention can be accurate to within about 1 gram and preferably to within about 0.1 gram or less. Alternatively, the volume of the sputter target can be measured anytime prior to being sputtered by the user, and preferably, prior to being supplied to the user, for example, before the target is bonded to the backing plate. Subsequently, the volume of the sputtered target can be measured anytime thereafter, for example, after separating the sputtered target from the spent target assembly. A comparison between the measured volumes of the supplied sputter target and the sputtered target can be used to determine the amount of target material consumed by the user in sputtering. The mass or volume of the sputtered target can be measured at anytime after sputtering and can be measured multiple times, for example, after multiple sputterings. Measurement of the volumes and/or masses of the sputter target and the sputtered target can be made by the supplier, the user, or any agents thereof. Measurements made by the user can be reported to the supplier based on designated times. The user can also determine the amount of target consumed for any individual target or target inventory (e.g., more than one target) and report the amount to the supplier. Other techniques can be used to determine the amount of target material consumed by the user.

As to charging the user for the amount of sputter target consumed by sputtering, the user is billed or charged or otherwise held financially responsible for the amount of target material consumed in the sputtering process, or, for the amount of target material not returned to the supplier or the supplier's agent. In one embodiment of the present invention, charging the user occurs at predetermined time intervals, for example, on a monthly basis. Another option involves charging the customer a fee at the time of delivery (e.g., to cover the fabrication costs of the sputtering target assembly). According to another embodiment, charging the user can coincide with designated events, such as upon determination of the amount of target material consumed, or upon return of the spent target assembly to the supplier or an agent of the supplier. The user can be charged for the amount of target material consumed or not returned on an individual target basis or collectively for an inventory of targets, or both. In another embodiment, or optionally in combination with one or more of the embodiments, the user is charged interest on the value of the sputtering target for the period beginning at a time that the sputtering target assembly is supplied to the user and ending at such time that the user is invoiced, or a portion of that period, or any other defined period of time.

In one embodiment of the present invention, the method includes returning by the user or an agent thereof the spent target assembly to the supplier or the supplier's agent. The steps of determining the amount of sputter material consumed by the user and charging the user for the determined amount according to the present invention are preferably performed upon the return of the spent target assembly to the supplier or the supplier's agent by the user or the user's agent. The amount of sputter target material consumed can be that amount of sputter target material that is not returned to the supplier for any given sputtering target assembly. Any means to track and determine the amount used and/or the amount returned can be used. A computer program can be used to track and determine costs. Bar codes or other tracking devices can be associated with each shipment to the manufacturer and then a bar code or other tracking device can be returned in order to know what shipment is being returned unused and even the original weight of the target. With the present invention, each individual shipment and use can be tracked and billed or multiple shipments and/or multiple returns can be combined into a single bill. Any combination can be used.

In one embodiment of the present invention, the method further includes charging the user a user fee on the sputtering target assembly supplied. The user fee can be independent of the charge for the amount of consumed target material. In one embodiment of the present invention, the method further includes charging the user a deposit fee on the sputtering target assembly supplied. Upon return of the spent target assembly, the deposit on the sputtering target assembly can be credited to the user. The amount of the deposit returned can be based upon any factors regarding the condition of the returned spent target assembly, including, but not limited to, the amount of sputtered target material (e.g., under or incomplete sputtering), damage to the sputter target assembly including the sputter target and the backing plate components, contamination of the sputter target material, as well as factors such as the length of time that the user possesses the sputtering target assembly (e.g., “overdue”), and the like. Optionally, the deposit fee charged for any spent target assembly returned can be credited towards the supply of any new sputtering target assembly, such that a “standing” deposit fee is maintained for any given inventory of sputtering target assemblies supplied to and in the possession of the user. Optionally, the user of the sputtering target assembly can be charged a fee for returning the spent target assembly. Such a fee can reflect costs associated with the return of the spent target assembly, including, but not limited to the packaging, shipping, storage, rent, and other handling of the spent target assembly.

In another embodiment of the present invention, the method of supplying a sputter target to a user can comprise a bailment in which the supplier is the bailor, the user is the bailee, and the sputtering target assembly constitutes the bailed goods. In this particular embodiment no transfer of ownership of the supplied sputter target occurs until the point at which it is determined what amount of the target material is retained by the user in the formation of sputtered products.

In one embodiment of the present invention the spent target assembly is reclaimed or recycled. The spent target assembly can be returned by the user to the supplier or someone else for recycling. Any method of recycling can be used. Recycling can include separation of the target from the backing plate by any method, including, for example, the method described in U.S. patent application Ser. No. 09/527,053 filed on Oct. 4, 2002, incorporated in its entirety by reference herein. This step encourages the return of a spent target assembly for reprocessing. Reprocessing of spent target assemblies reduces the need to mine and refine or to replace the amount of target grade metal that would otherwise be discarded as scrap metal. Furthermore, the method serves as a quality control process by controlling the introduction of undesirable impurities in the scrap metal that is alternately reprocessed by the sputtering target manufacturer.

The present invention has many advantages, including benefits to the fabricator from the above practice since, typically in the business, spent target assemblies are an undesirable byproduct of the sputtering process which causes loss of revenue to the fabricator. According to the method of the present invention, the scrap downgrade cost is reduced. As discussed above, scrap downgrade is equivalent to the total value created by both the primary metal processor and the sputtering target manufacturer between the melt feedstock or similar stage and the generation of a spent target assembly, plus the profit associated with the sale of the sputtering target assembly by the sputtering target manufacturer to the user. The method provides that the fabricator is charged for neither the value created by the primary metal processor to the melt feedstock to the point of supplying the mill forms to the manufacturer, nor the associated profit therefrom (e.g., for the sputtering target material that is not consumed by the end user). Another benefit of the method is that the overall manufacturing cost of the sputtering target manufacturer is additionally reduced since the fabricator is charged only for the target material consumed or used for fabricating the sputtered article. Therefore, the fabricator is charged for less metal material than it would be by the traditional business model. Furthermore, the method promotes the efficient use of target material by the user since the user is effectively being charged a fee for use and is responsible for wasting of target material.

Other embodiments of the present invention will be apparent to those skilled in the art from consideration of the present specification and practice of the present invention disclosed herein. It is intended that the present specification and examples be considered as exemplary only with a true scope and spirit of the invention being indicated by the following claims and equivalents thereof.

What is claimed is:

1. A method of supplying a sputter target, comprising:
(a) supplying a sputtering target assembly to a user or an agent thereof where a sputter target of said sputtering target assembly is sputtered to form a spent target assembly;
(b) determining an amount of said sputter target consumed by said sputtering; and
(c) charging said user based on said amount or an amount not returned.

2. The method of claim 1, further comprising returning by said user or an agent thereof said spent target assembly to a supplier or an agent thereof.

3. The method of claim 2, further comprising charging said user a separate fee for assembling, shipping and/or handling of said spent target assembly and/or new sputtering target assembly, or both.

4. The method of claim 1, further comprising charging said user interest on said sputtering target assembly for a period beginning at a time said sputtering target assembly is supplied to said user and ending at a time said user is invoiced, or a portion of said period, or other defined period of time.

5. The method of claim 1, wherein said step (c) occurs at predetermined time intervals.

6. The method of claim 2, wherein said step (c) occurs upon said returning of said spent target assembly.

7. The method of claim 1, further comprising charging said user a user fee for said sputtering target assembly.

8. The method of claim 1, further comprising charging said user a deposit fee on said sputtering target assembly.

9. The method of claim 1, wherein supplying said sputtering target assembly comprises a bailment.

10. The method of claim 1, wherein an ownership title in said sputtering target assembly remains with said supplier.

11. The method of claim 2, wherein said supplier is a sputter target manufacturer.

12. The method of claim 2, wherein said user is a fabricator.

13. The method of claim 1, wherein said sputter target comprises a mill form.

14. The method of claim 1, further comprising recycling said spent target assembly.

15. The method of claim 1, wherein said sputter target comprises a valve metal.

16. The method of claim 1, wherein said sputter target comprises tantalum.

17. The method of claim 1, wherein said sputter target comprises niobium.

18. The method of claim 1, wherein said sputter target comprises titanium.

19. The method of claim 1, wherein the sputter target comprises copper.

20. The method of claim 1, wherein said sputter target comprises aluminum.

21. The method of claim 1, further comprising recycling said spent target assembly.

22. The method of claim 1, wherein an additional fee is charged for returning a damaged sputtering target assembly or portion thereof.

23. The method of claim 21, wherein said damaged sputtering target assembly excludes the sputter target consumed by sputtering.

24. The method of claim 21, wherein said additional fee is charged to said user as a deposit which is refunded to said user upon return of an undamaged sputter target assembly, or said deposit is applied towards any damage to said sputtering target assembly.

25. A method of supplying a sputter target, comprising:
(a) supplying a sputtering target assembly to a user where a sputter target of said sputtering target assembly is sputtered to form a spent target assembly;
(b) returning said spent target assembly to said supplier or an agent thereof, and
(c) charging said user for an amount of said sputter target that is not returned.

26. The method of claim 1, further comprising charging said user a fee upon delivery of said sputtering target assembly for the cost to assemble and test a said sputtering target assembly.
